(19) United States
(12) Patent Application Publication
(10) Pub. No.: US 2012/0099326 A1
(43) Pub. Date: Apr. 26, 2012

(54) Flexible light emitting diode lighting process and assembly

(76) Inventors: Steven G. Hammond, Bemus Point, NY (US); Craig W. Hefright, Russell, PA (US)

(21) Appl. No.: 12/912,718

(22) Filed: Oct. 26, 2010

(51) Int. Cl. F21V 5/04; H01L 21/56

(52) U.S. Cl. 362/311.02; 438/27; 257/E21.502

(57) ABSTRACT

A light emitting diode lighting assembly for mounting to a curved mounting surface, such as a vehicle surface, includes a plurality of light emitting diodes, a circuit board, and a molded polymer section for surrounding and insulating the LEDs against the circuit board. The lighting assembly also includes a lens and a flexible molded housing surrounding a perimeter of the lens and the circuit board for sealing the lens to the circuit board.

### BRIEF DESCRIPTION OF THE DRAWINGS

FIG. 1 is a perspective view of one embodiment of the Flexible Light Emitting Diode Lighting Assembly.

FIG. 2 is a side view of the embodiment of FIG. 1.

FIG. 3 is a back perspective view of the Flexible Light Emitting Diode Lighting Assembly.

FIG. 4 is a bottom view of the Flexible Light Emitting Diode Lighting Assembly.

FIG. 5 is a top view of the Flexible Light Emitting Diode Lighting Assembly.

FIG. 6 is a top view of a circuit board having a plurality of Light Emitting Diodes connected thereto.

FIG. 7 is a top view of the circuit board of FIG. 10 further including a first molded material.

FIG. 8 is a bottom perspective view of the assembly as shown in FIG. 7, further including a lens.

FIG. 9 is a bottom perspective view of one embodiment of a Light Emitting Diode Assembly.

FIG. 10 is a process flow chart of the process of manufacturing a Light Emitting Diode Lighting Assembly.

FIG. 11 is a top view of another embodiment of a partially formed Flexible Light Emitting Diode Lighting Assembly.

FIG. 12 is a bottom view of the partially formed Flexible Light Emitting Diode Lighting Assembly of FIG. 11.

FIG. 13 is a bottom view of another embodiment of a fully formed Flexible Light Emitting Diode Lighting Assembly.

FIG. 14 is a top view of another embodiment of a fully formed Flexible Light Emitting Diode Lighting Assembly.

FIG. 15 is a top perspective view of another embodiment of a Light Emitting Diode Lighting Assembly.

FIG. 16 is a side cross-sectional view of another embodiment of a Light Emitting Diode Lighting Assembly.

FIG. 17 is a perspective, cross-sectional view of an additional embodiment of the Flexible Light Emitting Diode Lighting Assembly.

FIG. 18 is a side, cross-sectional view of the additional embodiment of the Flexible Light Emitting Diode Lighting Assembly of FIG. 17.

FIGS. 19-21 are top perspective, top and side views of one embodiment of the Flexible Light Emitting Diode Lighting Assembly.

FIG. 22 is a side cross-sectional view of the lens of the Flexible Light Emitting Diode Lighting Assembly.

FIG. 23 is another cross-sectional view of the lens of the Flexible Light Emitting Diode Lighting Assembly.

FIG. 24 is an enlarged view of an optical element of the Flexible Light Emitting Diode Lighting Assembly of FIG. 23.

FIGS. 25 and 26 illustrate beam patterns created by internal optical elements and external optical elements, respectively.

### SUMMARY

A light emitting diode lighting assembly for mounting to a curved mounting surface, such as a vehicle surface, is disclosed. The lighting assembly includes a plurality of light emitting diodes (LEDs), a circuit board for providing electrical current to the LEDs. The circuit board may also have a resistor electrically connected thereto. A molded polymer section is molded around the LEDs and resistor, thereby surrounding and insulating such electrical components against the circuit board.

The circuit board and molded polymer section are adapted to fit within a cavity of a lens having optical surfaces. The lens is positioned such that an air gap is present between the top surfaces of the LEDs and the lens. The lighting assembly also includes a flexible molded housing surrounding a perimeter of the lens and the circuit board for sealing the lens to the circuit board. The flexible molded housing is molded while maintaining the air gap between the top surfaces of the LEDs and the lens.

The lighting assembly also includes an adhesive material positioned against a back portion of the flexible molded housing for attaching the lighting assembly to a surface without the use of fasteners.

### DETAILED DESCRIPTION OF THE EMBODIMENTS

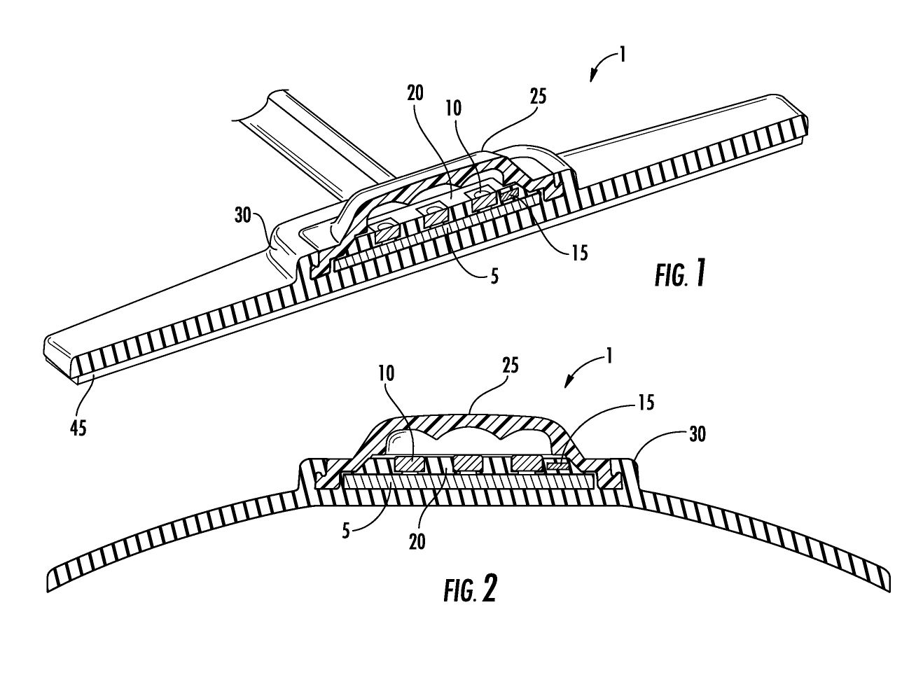

As illustrated in FIGS. 1 and 2, a first embodiment of a flexible light emitting diode lighting assembly 1, hereinafter “lighting assembly 1,” includes a circuit board 5 having a plurality of light emitting diodes, one of which is indicated at 10, affixed thereto. Circuit board 5 also includes an electrically connected resistor 15. A first molded portion 20 surrounds the light emitting diodes 10 and resistor, thereby sealing such components to circuit board 5. A lens 25 is positioned over circuit board 5 such that lens 25 covers first molded portion 20 and circuit board 5. A flexible molded housing 30 surrounds a lower portion of lens 25 to seal circuit board 5 and prevent moisture from entering between lens 25 and flexible molded housing 30. In the embodiment shown in FIGS. 2 and 3, housing 30 includes extension wings 40, which extend laterally from said circuit board and allow lighting assembly 1 to be mounted to a curved surface.

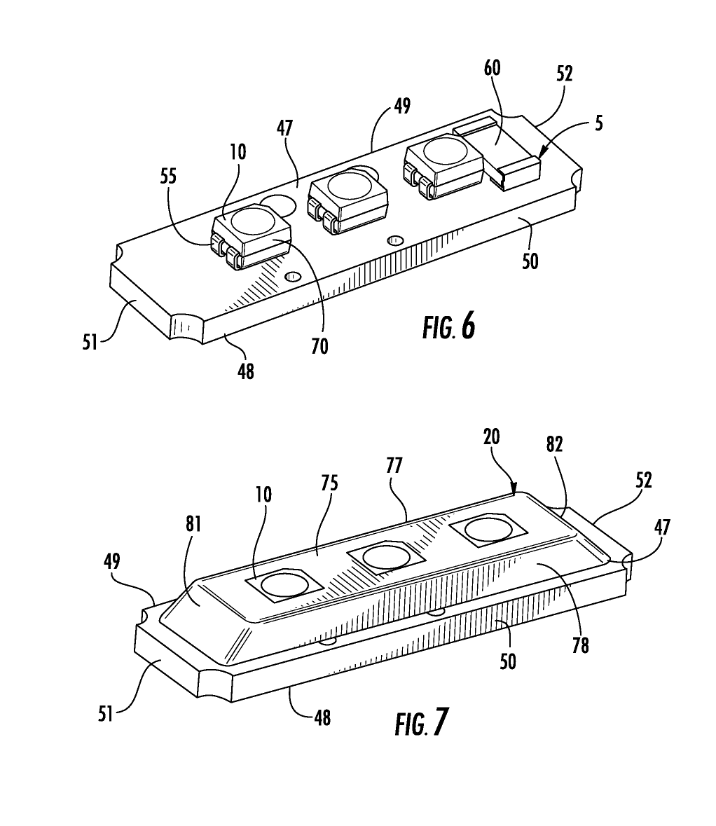

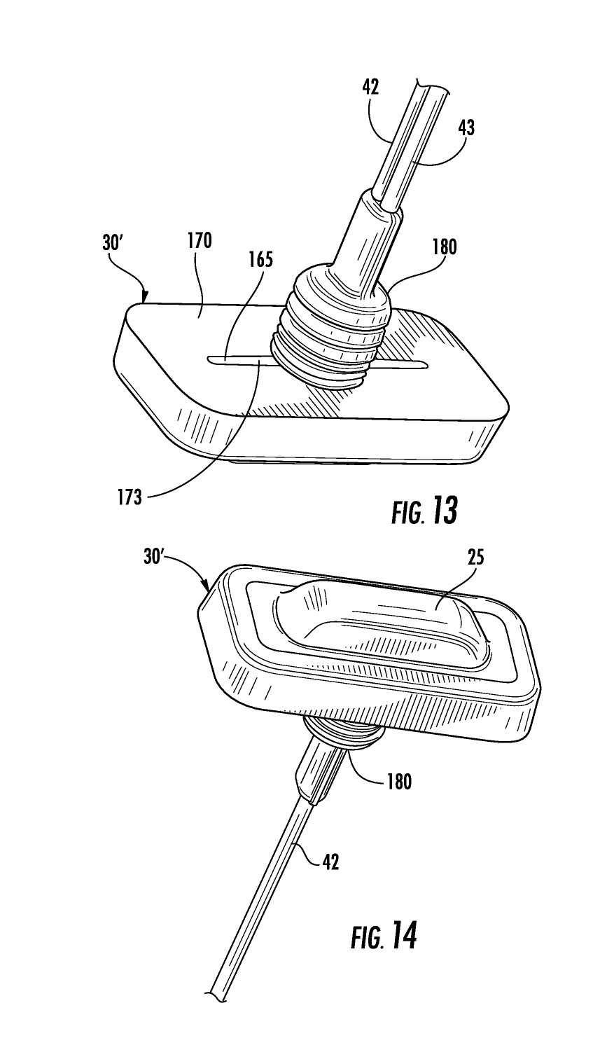

FIGS. 3-5 illustrate a side perspective view, bottom perspective view, and top view of lighting assembly 1, respectively, with wires 42, 43 extending from a side edge 44 of flexible molded housing 30. Wires 42, 43 are used to attach lighting assembly 1 to a vehicle wiring harness (not shown). Wires 42, 43 may exit side edge 44 of lamp assembly as shown in FIGS. 3-5, for vehicles where harnesses are run on an exterior of a vehicle. Alternatively, wires 42, 43 may exit a bottom surface of lamp assembly 1 to conceal the wires, as will be described in detail with reference to FIGS. 11-14.

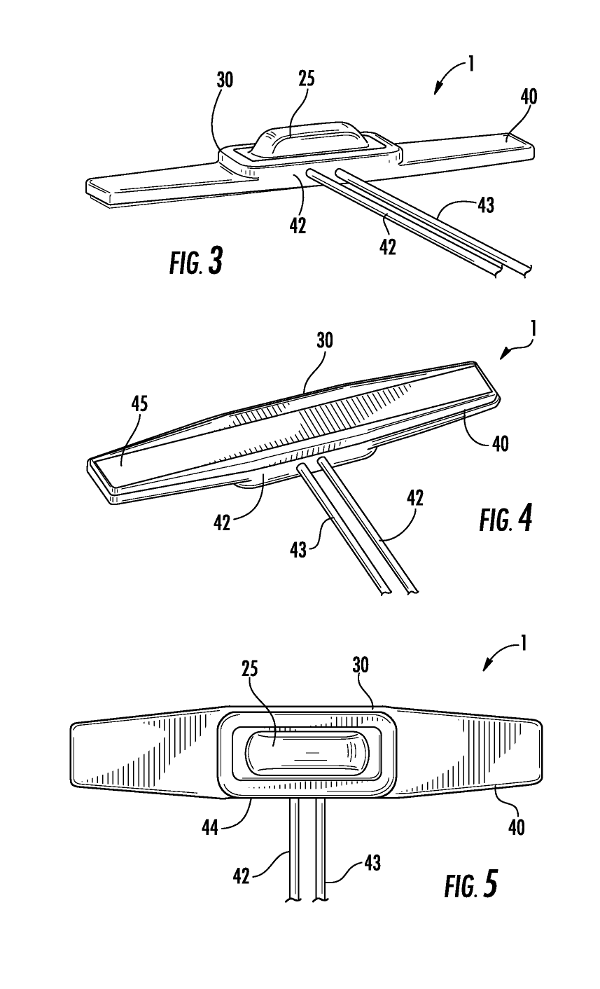

As shown in FIG. 4, lighting assembly 1 includes an adhesive material, such as tape, 45 affixed to a bottom portion of flexible molded housing 30 for attaching lighting assembly to a mounting surface (not shown) in a manner that does not require fasteners that damage the mounting surface. Extension wings 40 of flexible molded housing, along with adhesive material 45 facilitate the attachment of lighting assembly 1 to a curved surface without the use of additional fasteners or tools.

Each component of lighting assembly 1 will now be described in greater detail with reference to FIGS. 6-9. Initially, with reference to FIG. 6, circuit board 5 includes a top surface 47, a bottom surface 48, a pair of side edges 49, 50 and ends 51, 52. Circuit board 5 provides electrical current to LEDs 10 via electrical connection 55. LEDs 10 are positioned on top surface of circuit board 5. A resistor 60 is also provided on circuit board 5 for controlling the electrical current supplied by wires 42, 43 and circuit board 5 to LEDs 10. Circuit board 5 also acts as a heat sink for drawing heat away from LEDs 10. In the embodiment shown, circuit board 5 is not flexible. However, in other embodiments circuit board 5 may be flexible. Circuit board 5 is not flexible since it is desirable for LEDs 10 to have the same planar relationship relative to one another. By maintaining LEDs 10 in the same plane, the photometric output of lighting assembly 1 is not altered.

LEDs 10 may be selected to meet photometric requirements of a variety of vehicle lighting applications, such as Clearance lamp, Side Marker lamp, or Identification Lamp, or Combination Clearance and Side Marker lamp as set forth by the SAE guidelines. We hereby incorporate by reference SAE J592e, July 1972, which describes photometric requirements of several lighting applications. In the embodiment shown in FIG. 6, LEDs 10 have a flat top face (not separately numbered) surrounded by LED potting compound. LEDs have a height 70, which indicates the distance from top surface 47 of circuit board 5 to flat top surface of LEDs 5. However, it should be understood that other types of LEDs may be used. In addition, LEDs 10 may be selected to emit a variety of different colored light, such as white, red or amber.

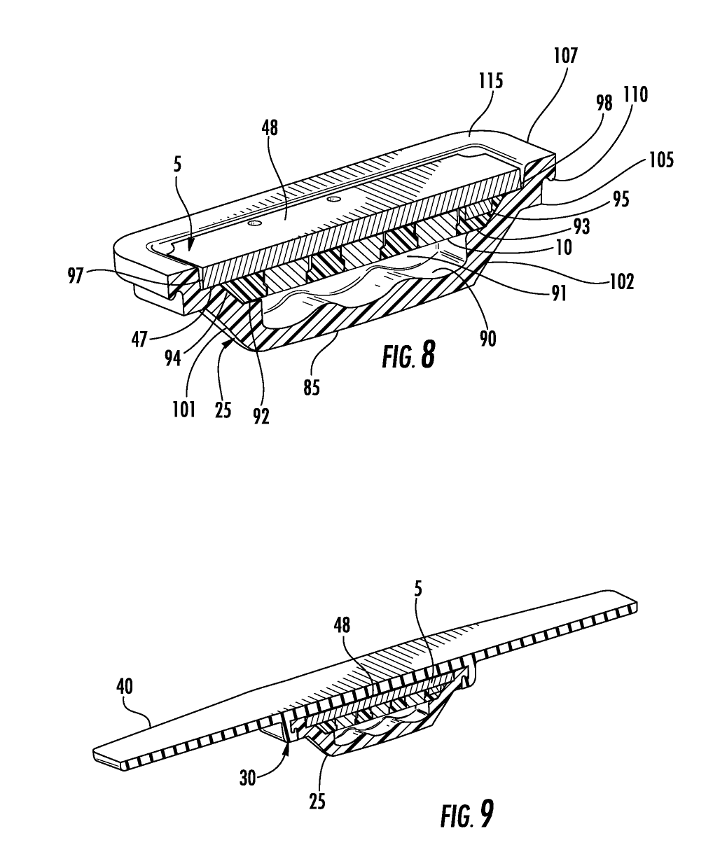

FIG. 7 illustrates molded portion 20 molded to top surface 47 of circuit board 5. Molded portion 20 adheres to circuit board 5 and surrounds LEDs 10, covering and protecting electrical connections 55. Resistor 60 is also fully surrounded and covered by molded portion 20. Molded portion 20 includes a top face 75, sides 77, 78 and sloped ends 81, 82. A polymer material such as a polyamide hot melt adhesive is used to form molded portion 20.

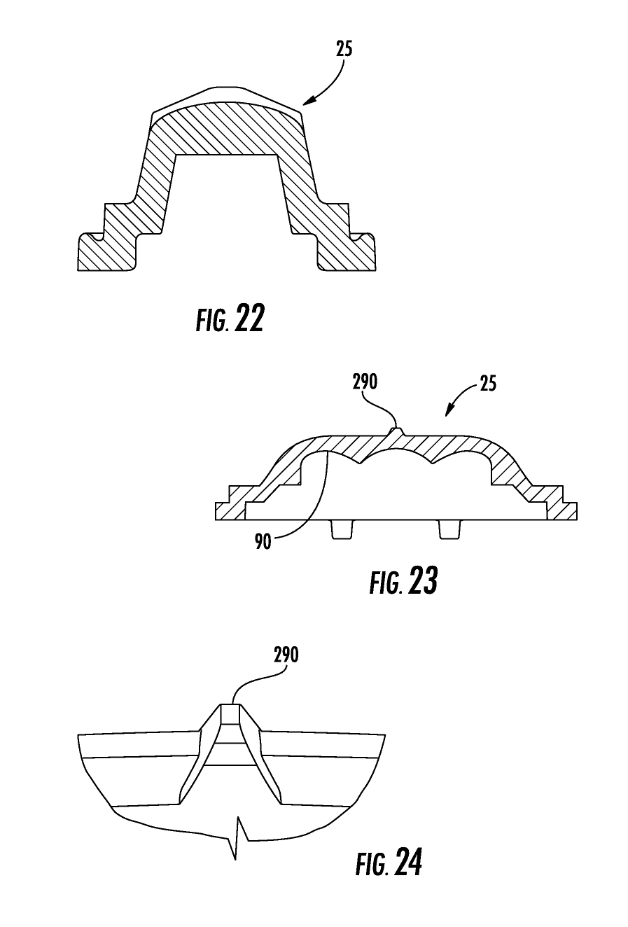

Lens 25, as illustrated in FIG. 8, is formed from an injection molded acrylic or polycarbonate plastic material and includes optical surfaces to disperse light emitted from LED's 10 to meet photometric requirements for the intended use of lighting assembly 1. Lens 25 includes an outer surface 85 and an inner surface having optical elements 90 (such as pillow optics) that are aligned with LEDs 10 for transmitting light. Outer surface 85 may be curved having differing radii each direction. In addition, outer surface 85 may include a protruding optical element 290 in the center of outer surface 85 of lens 25 to direct light to extreme angles (e.g. 85 to 90 degrees to face of lighting assembly 1). Protruding optical element 290 will be described with reference to FIGS. 17-26 below. An air gap 91 is maintained between the top surface of LEDs 10 and the inner surface optical elements 90 of lens 25. Inner surface of lens 25 also includes first interior abutment portions 92, 93 and interior slanted portions 94, 95 for abutting top surface 75 and sloped ends 81, 82 of molded portion 20. Lens 25 also includes second interior abutment portions 97, 98 for contacting a portion of top surface 47 of circuit board 5.

Lens 25 also includes outer slanted edges 101,102 extending downward from outer surface 85. Slanted edges 101, 102 terminate at a first circumferential ledge 105. A second circumferential portion 107 includes an upward extending lip 110 for engaging flexible housing 30 and a bottom circumferential surface 115, which is in substantially the same plane as bottom surface 48 of circuit board 5. In addition, the lens may be formed from a clear, amber, red or other color material.

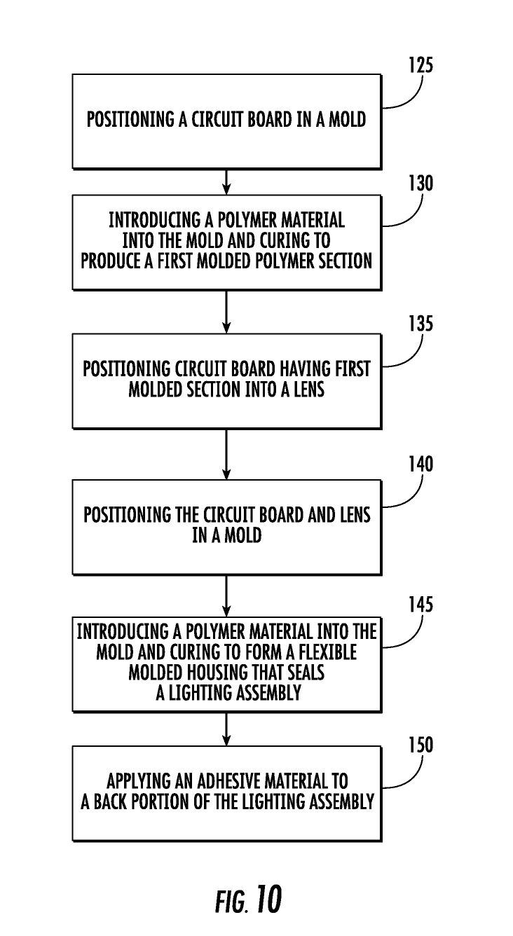

As illustrated in FIG. 9, flexible molded housing 30 surrounds circuit board 5 and lens 25 such that housing 30 seals circuit board 5 and lens 25. Molded housing contacts bottom surface 48 of circuit board 5. Lens 25 is sealed by molded housing 30 at first circumferential ledge 105 and second circumferential portion 107. In addition, molded housing 30 surrounds upward extending lip 110 of second circumferential portion 107 to further secure the seal between lens 25, circuit board 5, and housing 30. Housing is formed from a polymer material, such as a polyamide hot melt adhesive. As shown in FIG. 9, housing 30 may include extension wings 40 for facilitating the mounting of lighting assembly 1 on a curved surface. Thus, flexible housing 30 is used to conform to a vehicle surface, as well as seal the electrical components and lens cavity, preventing moisture ingress.

FIG. 10 illustrates the process of manufacturing an embodiment of lighting assembly 1. As indicated by numbers 125 and 130, circuit board 5 having LEDs 10 and resistor 15 are initially positioned into a mold. A thermoplastic polymer material is injected into the mold under low pressure such that it surrounds LEDs 10 and resistor 15. The molding tool includes spring loaded shut-off pins, as are known in the art. The shut off pins are required to shut off on the faces of LED's 10 during molding to prevent the faces of LEDs 10 from being covered during molding. The spring loaded shut off pins must have a large enough diameter pin to allow for LED alignment tolerances from assembly of circuit board 5, and (B) tolerances for inserting circuit board 5 into the molding tool.

The diameter of the spring loaded pins should not be so large such that the diameter extends beyond LEDs 10, since there is a change that the pin will be pushed back by injection pressure. In addition, the spring pressure must be light enough not to damage LEDs 10 or a solder joint, yet be strong enough to resist push back from injection pressure. Further, the travel of the shut-off pins, and level of travel in comparison to the material surrounding the LED's, must be enough to allow for the stack-up tolerances of circuit board 5 and LEDs 10, but can not be too deep or it will block light emitted from LEDs 10 at extreme angles.

Thus, the thermoplastic polymer material, such as polyamide, is injected into a molding tool capable of preventing the top surfaces of LEDs 10 from being covered by polymer during molding. Circuit board 5, lens 25 and polymer material are left in the mold to cure. When the polymer material is cured, the resulting part includes a first molded portion 20 surrounding and insulating LEDs 10, electrical contacts 55, and resistor 60 against top surface 47 of circuit board 5.

As indicated by 135 in FIG. 10, circuit board 5 with molded portion 20 is positioned within a cavity of lens 25. Lens 25 is formed from an injected molded acrylic or polycarbonate plastic material. Lens 25 includes optical elements 90 to disperse light emitted from LEDs 10 to meet requirements of the intended use for lighting assembly 1. Lens 25 includes structural features to assist in aligning circuit board 5 and first molded portion 20 within lens cavity. For example, first interior abutment portions 92, 93, interior slanted portions 94, 95, second interior abutment portions 97, 98 of lens 25 act as alignment features for circuit board 5 and molded portion 20. Correct alignment of circuit board 5, molded portion 20 and LEDs 10 is necessary such that air gap 91, between the inner surface of lens 25 and top surface of LEDs 10 is maintained to allow light to propagate through lens optical elements 90 at intended angles to meet photometry requirements.

As noted in FIG. 10, steps 140 and 125, circuit board 5 and lens 25 are positioned into a mold and a thermoplastic polymer, such as a polyamide hot melt adhesive material, is introduced into the mold such that it seals lens 25 and circuit board 5, while maintaining air gap 91. The polymer material surrounds first circumferential ledge 105, second circumferential portion 107 and upward extending lip 110 of lens 25 to assist in sealing lens 25 and circuit board 5. Bottom surface 48 of circuit board 5 is also sealed with the polymer material. The polymer material is then cured to form flexible molded housing 30. The mold may allow for the formation of extension wings 40, which are integrally formed with molded housing 30 with thermoplastic polymer in the molding process. Extension wings 40 allow lighting assembly 1 to be mounted to a flat, irregular, or curved surface down to a minimum 4.5″ radius.

Step 150 of the embodiment illustrated in FIG. 10 is directed to applying an adhesive material 45 against a back portion of molded housing 30 lighting assembly 1. In the embodiment disclose, adhesive material 45 is a double sided foam tape. However, the adhesive material may be any suitable material known in the art. Lamp is mounted with a double sided foam tape, eliminating the need for mounting hardware or special brackets.

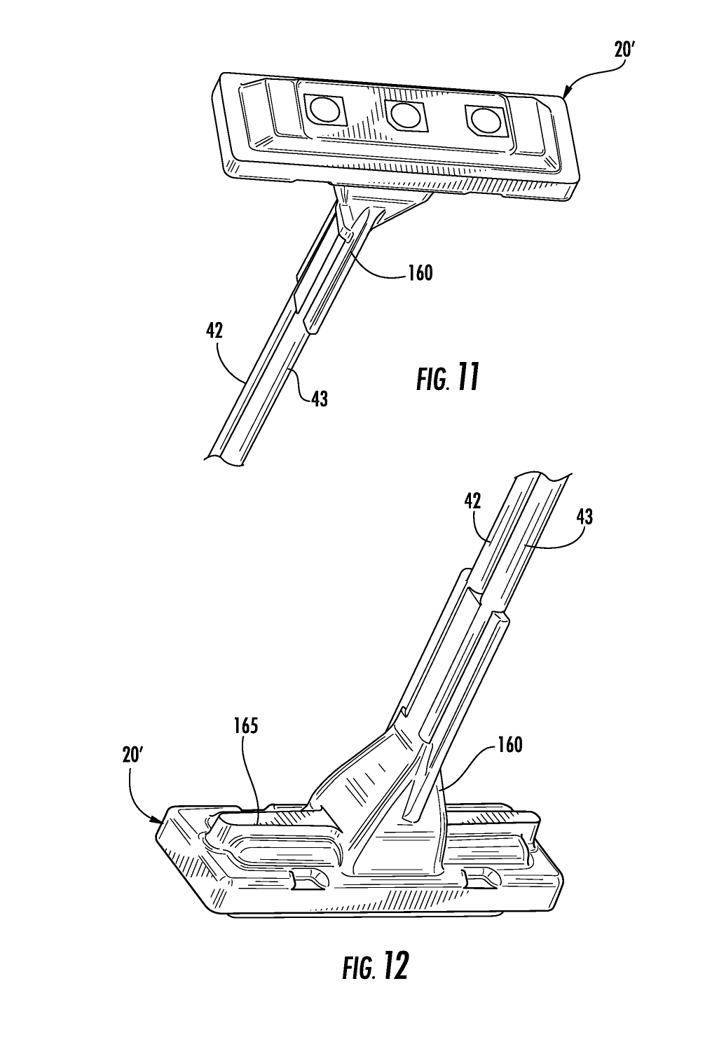

FIGS. 11-14 illustrate an alternate embodiment of lighting assembly 1′. As shown in FIGS. 11-12, wires 42, 43 exit from bottom surface 48 of circuit board 5. First molded portion 20′ surrounds circuit board 5 to seal LEDs 10, resistor 15 and any other electrical components. In addition, first molded portion 20′ extends to bottom portion 48 of circuit board 5 and includes an encasing portion 160 to contain wires 42, 43 extending from circuit board 5. Molded portion 20′ also includes a raised ridge 165 formed on bottom surface 48 of circuit board 5. Encasing portion 160, which is integrally formed with raised ridge 165, prevents wires 42, 43 from being exposing the wires during subsequent molding processes.

Following molding and curing of first molded portion 20′, lens 25 is positioned for molding. Flexible housing 30′ is molded around first molded portion 20′ and lens 25. Flexible housing 30′ surrounds lens and first molded portion 20′ such that moisture egress is prevented. Flexible housing 30′ includes a substantially flat bottom 170 having a slit opening 173 through which raised ridge 165 extends to further secure flexible housing 30′ to molded portion 20′. A plug 180 is also molded into flexible housing for covering encasing portion 160 of molded portion 20′. With the embodiment shown in FIGS. 11-14, a hole in the mounting surface is required to conceal wires, 42, 43, encasing 160 and plug 180. Plug 180 is molded such that it can fill a standard hole in a vehicle or other mounting surface. The polymeric material of encasing 160 and plug 180 also create a strain relief for wires 42, 43.

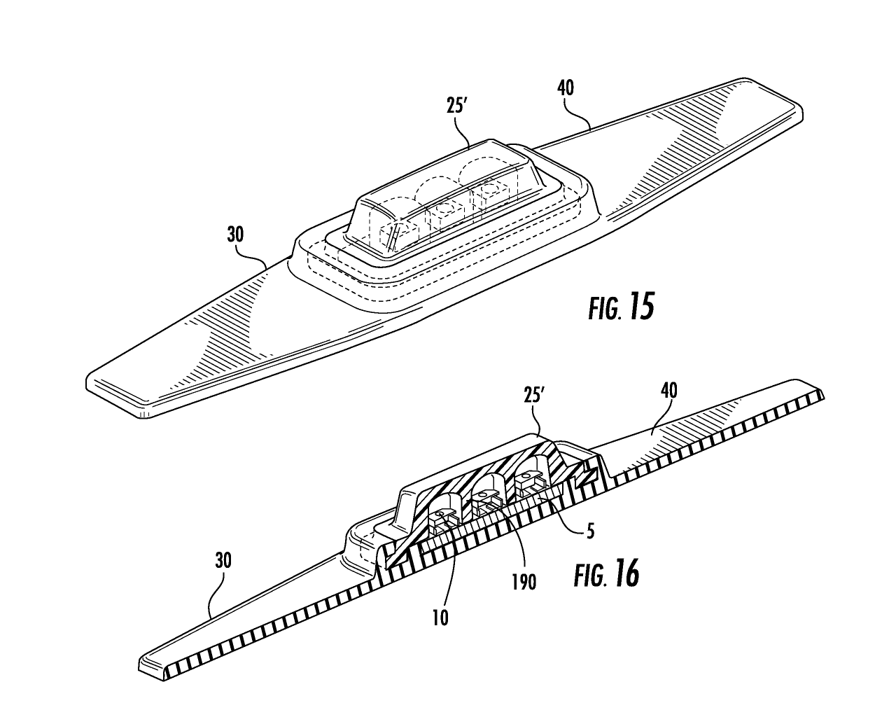

In yet another embodiment, as illustrated in FIGS. 15 and 16, lighting assembly does not include a first molded portion 20. In this embodiment, lighting assembly 1 includes LEDs 10, a circuit board 5, a lens 25′ and a flexible housing 30. Lens 25′ is configured to receive circuit board 5 with LEDs 10 with out requiring first molded portion 20 for positioning guidance. Lens 25′ includes extensions 190 positioned along an inner surface of lens 25′, dividing each optical element 90. Extensions abut top surface 47 of circuit board 5 to assist in aligning LEDs 10 with optical elements 90. Extension wings 40 are provided on flexible housing 30 to allow lighting assembly 1 to be fixed by adhesive to a flat or curved surface.

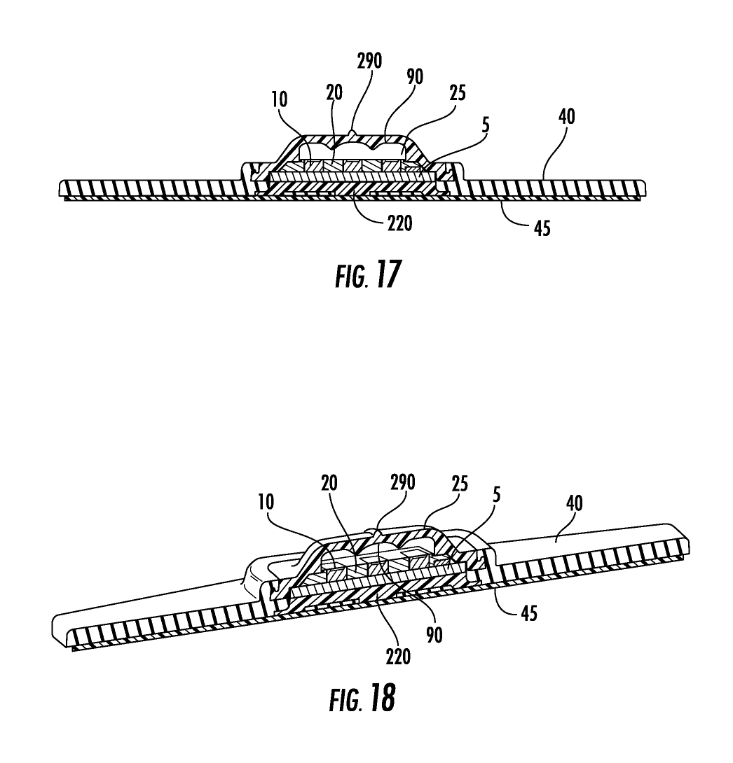

FIGS. 17-21 illustrate an additional embodiment of Flexible Light Emitting Diode Lighting Assembly 1. With reference to FIGS. 17 and 18, a bottom molded portion 220 is present on a bottom surface 48 of circuit board 5. Bottom molded portion 220 is molded during step 130 of FIG. 10 and is formed of the same polymer material as molded portion 20. The sealing of circuit board 5 and LEDs 10 is enhanced by bottom molded portion 220. An adhesive material 45, as described in connection with previous embodiments, is applied to the underside of bottom molded portion 220.

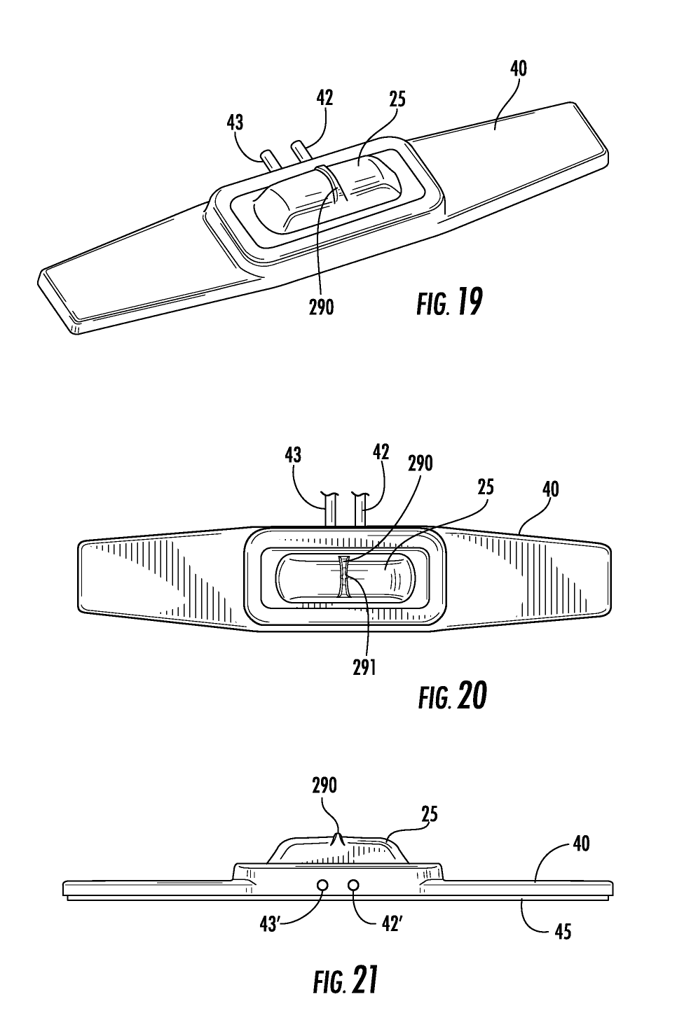

FIGS. 17-25 illustrate lighting assembly 1 having lens 25 with an outer surface 85 that is curved having differing radii each direction. In addition, outer surface 85 includes a protruding optical element 290 to direct light to extreme angles (e.g. 85 to 90 degrees to face of lighting assembly 1). FIG. 24 is an enlarged view of protruding optical element 290 showing flat edges (not labeled) for use in creating a light ray pattern. As best shown in FIG. 20, lens 25 includes a raised ridge 291 that bisects lens 25 along protruding optical element 290. Raised ridge 291 also contributes to the distribution of light rays from LEDs 10.

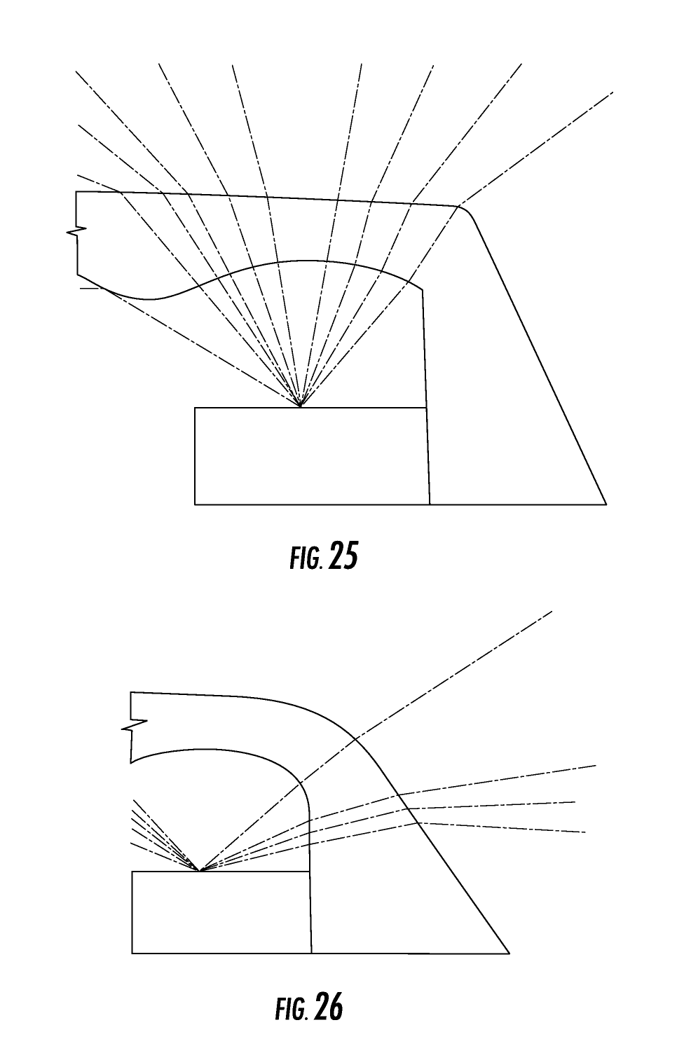

Inner optical surfaces 90 of lens 25, which are centered above each LED 10 produces a 0-56 degree light ray pattern. One internal optical surface 90 is illustrated above one LED 10 to illustrate the 0-56 degree light ray pattern in FIG. 25. Similar optical elements are positioned above the additional LEDs 10 in lighting assembly 1. Outer optical elements of lens 25, including protruding optical element 290 with raised ridge 291, and internal optical elements at the end of the lens (not separately labeled), work in conjunction to direct light out to the sides of the lamp (56-100 degrees) to meet industry requirements at extreme angles. FIG. 26 illustrates the 56-100 degree light ray pattern created by lens 25 over one of LEDs 10.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

We claim:

1. A light emitting diode lighting assembly comprising:
at least one light emitting diode;
a circuit board for providing electrical current to said at least one light emitting diode;
a molded polymer section surrounding and insulating said at least one light emitting diode against said circuit board;
a lens in which said molded polymer section and circuit board are positioned such that an air gap is present between a top surface of said at least one light emitting diode and said lens;
a flexible molded housing surrounding a perimeter of said lens and said circuit board for sealing said lens to said circuit board, while maintaining the air gap between said top surface of said at least one light emitting diode and said lens; and
an adhesive material positioned against a back portion of said flexible molded housing for attaching said light emitting diode lighting assembly to a surface.

3. The light emitting diode lighting assembly of claim 1 further comprising a second molded polymer section for sealing a bottom surface of said circuit board.

4. The light emitting diode lighting assembly of claim 1 wherein said molded polymer section and said flexible molded housing are formed of polyamide.

5. The light emitting diode lighting assembly of claim 1 wherein the adhesive material is a double sided foam tape.

6. The light emitting diode lighting assembly of claim 1 wherein the lens includes an outer surface and an inner surface having at least one optical element corresponding to one of said at least one light emitting diode.

7. The light emitting diode lighting assembly of claim 6 wherein the lens includes pillow optical elements on an internal surface and a protruding optical element on an outer surface.

8. The light emitting diode lighting assembly of claim 7 wherein the lens is configured to meet the photometric requirements for use as a Clearance lamp, Side Marker lamp, Identification Lamp, or Combination Clearance and Side Marker lamp.

9. The light emitting diode lighting assembly of claim 1 wherein the flexible molded housing includes flexible extension wings for curving such that said light emitting diode lighting assembly may be adhesively attached to a curved surface.

10. The light emitting diode lighting assembly of claim 1 wherein said molded polymer section further includes an encasing portion for containing wires extending from said circuit board and said flexible molded housing further includes a plug for covering said encasing portion of said molded polymer section, wherein said plug is adapted to fit within an opening in a mounting surface.

11. A light emitting diode lighting assembly comprising:
at least one light emitting diode;
a circuit board for provides electrical current to said at least one light emitting diode;
a molded polymer section surrounding and insulating said at least one light emitting diode against said circuit board;
a lens positioned over said molded polymer section such that an air gap is present between a top surface of said at least one light emitting diode and said lens;
a flexible molded housing surrounding a perimeter of said lens and said circuit board for sealing said lens to said circuit board, while maintaining the air gap between said top surface of said at least one light emitting diode and said lens, said flexible molded housing having flexible extension wings extending outward from said circuit board; and
an adhesive material positioned against a back portion of said flexible molded housing for attaching said light emitting diode lighting assembly to a surface;
wherein said flexible molded housing having flexible wing portions which curve such that said light emitting diode lighting assembly may be adhesively attached to a curved surface.

12. The light emitting diode lighting assembly of claim 11 further comprising a second molded polymer section for sealing a bottom surface of said circuit board.

13. The light emitting diode lighting assembly of claim 11 wherein said molded polymer section and said flexible molded housing are formed of polyamide.

14. The light emitting diode lighting assembly of claim 11 wherein the adhesive material is a double sided foam tape.

15. The light emitting diode lighting assembly of claim 11 wherein the lens includes an outer surface and an inner surface having at least one optical element corresponding to one of said at least one light emitting diode.

16. The light emitting diode lighting assembly of claim 15 wherein the lens includes pillow optical elements on an internal surface and a protruding optical element on an outer surface.

17. The light emitting diode lighting assembly of claim 16 wherein the lens is configured to meet the photometric requirements for use as a Clearance lamp, Side Marker lamp, Identification Lamp, or Combination Clearance and Side Marker lamp.

18. The light emitting diode lighting assembly of claim 11 wherein said molded polymer section further includes an encasing portion for containing wires extending from said circuit board and said flexible molded housing further includes a plug for covering said encasing portion of said molded polymer section, wherein said plug is adapted to fit within an opening in a mounting surface.

19. Method of producing a light emitting diode lighting assembly, comprising:
providing a circuit board having at least one light emitting diode electrically connected thereto;
positioning said circuit board in a mold;
introducing a polymer material into said mold such that said at least one light emitting diode is surrounded by a polymer material to affix the at least one light emitting diode to said circuit board, wherein the polymer material is prevented from covering a top surface of said least one light emitting diode;
curing said polymer material in said mold to form a molded polymer section;
positioning a lens over said molded polymer section such that an air gap is present between said top surface of said at least one light emitting diode and said lens;
positioning said circuit board and said lens in a mold;
introducing a polymer material into said mold such that said polymer material surrounds a perimeter of said lens and said circuit board for sealing said lens to said circuit board, while maintaining the air gap between said top surface of said at least one light emitting diode and said lens; and
curing said polymer material in said mold to form a flexible molded housing; and
applying an adhesive material positioned against a back portion of said flexible molded housing for attaching said light emitting diode lighting assembly to a surface without the use of fasteners.

20. The method of producing the light emitting diode lighting assembly of claim 19 wherein said molded polymer section further includes an encasing portion for containing wires extending from said circuit board and said flexible molded housing further includes a plug for covering said encasing portion of said molded polymer section, wherein said plug is adapted to fit within an opening in a mounting surface.

21. The method of producing the light emitting diode lighting assembly of claim 19 wherein the flexible molded housing includes flexible extension wings for curving such that said light emitting diode lighting assembly may be adhesively attached to a curved surface.
